(19) United States
(12) Patent Application Publication
(10) Pub. No.: US 2026/0182368 A1
(43) Pub. Date: Jun. 25, 2026

(54) SEMICONDUCTOR PACKAGE WITH CARBON NANO FILLER PARTICLES

(71) Applicant: SAMSUNG ELECTRONICS CO., LTD., Suwon-si (KR)

(72) Inventor: JAE-IN WON, Suwon-si (KR)

(73) Assignee: SAMSUNG ELECTRONICS CO., LTD., Suwon-si (KR)

(21) Appl. No.: 19/257,999

(22) Filed: Jul. 2, 2025

(30) Foreign Application Priority Data
Dec. 23, 2024 (KR) 10-2024-0194255

(51) Int. Cl. H01L 23/373; H01L 23/00; H01L 23/29; H01L 23/31; H01L 23/498; H01L 25/065; H01L 25/18; H10B 80/00; H10D 80/30

(52) U.S. Cl. CPC H10W 40/251; H10W 40/254; H10W 74/121; H10W 74/473; H10B 80/00; H10D 80/30; H10W 72/325; H10W 72/351; H10W 72/353; H10W 72/354; H10W 72/884; H10W 74/15; H10W 90/00; H10W 90/20; H10W 90/24; H10W 90/297; H10W 90/701; H10W 90/722; H10W 90/724; H10W 90/732; H10W 90/734; H10W 90/752; H10W 90/754

(57) ABSTRACT

A semiconductor package includes: a substrate; a semiconductor device on the substrate; and a first mold layer on a first surface of the semiconductor device and a surface of the substrate, in which the first mold layer comprises a first resin layer and first filler particles in the first resin layer, in which each of the first filler particles comprises a first core portion and a first coating layer surrounding at least a portion of the first core portion, in which the first core portion comprises a carbon material, and in which the first coating layer comprises a carbon-excluded inorganic material.

### CROSS-REFERENCE TO RELATED APPLICATIONS

This U.S. non-provisional patent application claims priority under 35 U.S.C. §119 of Korean Patent Application No. 10-2024-0194255, filed on Dec. 23, 2024, the entire contents of which are hereby incorporated by reference.

### BACKGROUND

The present disclosure herein relates to a semiconductor package with carbon nano filler particles.

A semiconductor package is an integrated circuit chip implemented in a form suitable for using in an electronic product. In general, the semiconductor package is manufactured by mounting a semiconductor chip on a printed circuit board (PCB), and electrically connecting the same by using a bonding wire or a bump. With development of the electronics industry, research on improving reliability and durability of the semiconductor package is variously conducted. According to U.S. Pat. No. 9,859,199 and others, a mold layer covering the semiconductor chip is formed in the semiconductor package in order to protect the semiconductor chip. However, due to the mold layer, heat-dissipation characteristics may be deteriorated or a warpage phenomenon may occur in the semiconductor chip.

### SUMMARY

The present disclosure provides a semiconductor package with improved reliability.

A technical goal of the present disclosure is not limited to the goal mentioned above, and other technical goals that are not mentioned may be clearly understood from description below by those skilled in the art.

According to an aspect of the disclosure, a semiconductor package includes: a substrate; a semiconductor device on the substrate; and a first mold layer on a first surface of the semiconductor device and a surface of the substrate, in which the first mold layer comprises a first resin layer and first filler particles in the first resin layer, in which at least one of the first filler particles comprises a first core portion and a first coating layer surrounding at least a portion of the first core portion, in which the first core portion comprises a carbon material, and in which the first coating layer comprises a carbon-excluded inorganic material.

According to an aspect of the disclosure, a semiconductor package includes: a substrate; one or more external connection terminals bonded to a first surface of the substrate; at least one semiconductor device on the substrate; a mold layer on a second surface of the substrate and at least a surface of the at least one semiconductor device; at least two internal connection members between the at least one semiconductor device and the substrate, and configured to connect the at least one semiconductor device and the substrate; and an underfill layer between the at least one semiconductor device and the substrate, and configured to fill spaces between the at least two internal connection members, in which the underfill layer comprises a first resin layer and first filler particles dispersed in the first resin layer, in which at least one of the first filler particles comprises a first core portion and a first coating layer surrounding the first core portion, in which the first core portion comprises at least one of graphene, carbon nanotube, diamond, or graphite, in which the first coating layer has a structure of a single layer or a structure of multiple layers, in which the first coating layer comprises at least one of silica, alumina, magnesium oxide, or boron nitride, and in which the first filler particles have a form of an ellipse or a sphere.

According to an aspect of the disclosure, a semiconductor package includes: a substrate; a semiconductor device on the substrate; an adhesive layer between the semiconductor device and the substrate; and a mold layer on a first surface of the semiconductor device and a surface of the substrate, in which the adhesive layer comprises a first resin layer and first filler particles in the first resin layer, in which at least one of the first filler particles comprise a first core portion and a first coating layer surrounding at least a portion of the first core portion, in which the first core portion comprises a carbon material, and in which the first coating layer comprises a carbon-excluded inorganic material.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a cross-sectional view of a semiconductor package according to embodiments of the present disclosure;

FIGS. 2A to 2C are enlarged diagrams of part ‘P1’ of FIG. 1 according to embodiments of the present disclosure;

FIG. 3 is an enlarged diagram of part ‘P2’ of FIG. 1 according to embodiments of the present disclosure;

FIGS. 4A to 4D are cross-sectional views of a filler particle according to embodiments of the present disclosure;

FIG. 5 is a cross-sectional view of a semiconductor package according to embodiments of the present disclosure;

FIGS. 6A to 6C are enlarged diagrams of part ‘P2’ of FIG. 5 according to embodiments of the present disclosure;

FIG. 7 is a cross-sectional view of a semiconductor package according to embodiments of the present disclosure;

FIG. 8 is an enlarged diagram of part ‘P3’ of FIG. 7 according to embodiments of the present disclosure;

FIG. 9 is a cross-sectional view of a semiconductor package according to embodiments of the present disclosure;

FIGS. 10A to 10C are enlarged diagrams of part ‘P4’ of FIG. 9 according to embodiments of the present disclosure;

FIG. 11 is a cross-sectional view of a semiconductor package according to embodiments of the present disclosure;

FIG. 12 is a cross-sectional view of a semiconductor package according to embodiments of the present disclosure; and

FIG. 13 is a cross-sectional view of a semiconductor package according to embodiments of the present disclosure.

### DETAILED DESCRIPTION

Hereinafter, embodiments according to the present disclosure will be described in more detail with reference to the accompanying drawings in order to more specifically describe the present disclosure. In the present specification, terms showing a sequence such as first and second are used to distinguish components that perform the same function or similar functions, and may be renumbered according to a mentioned sequence.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

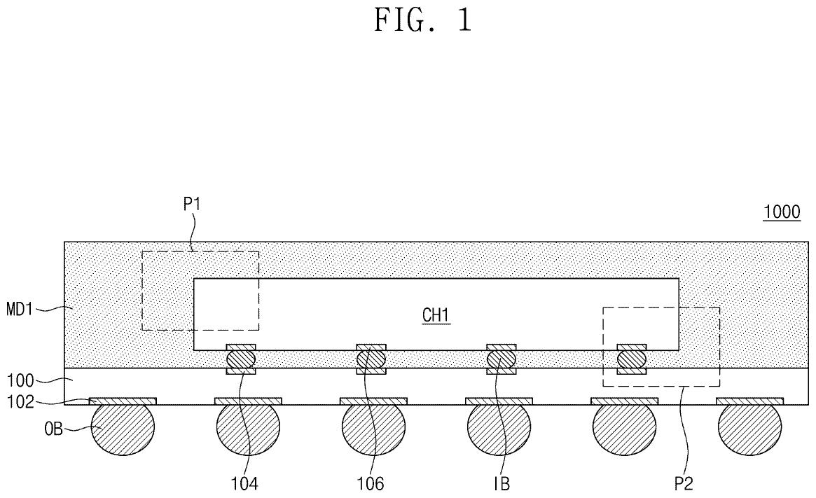

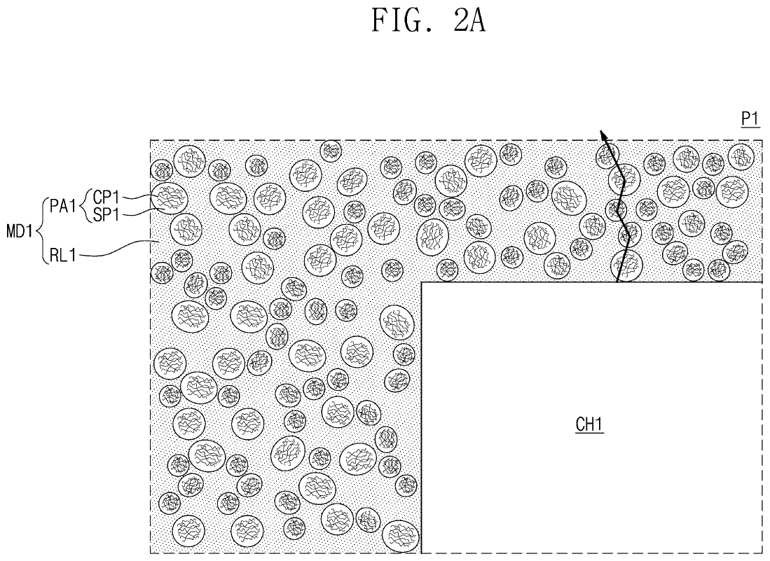

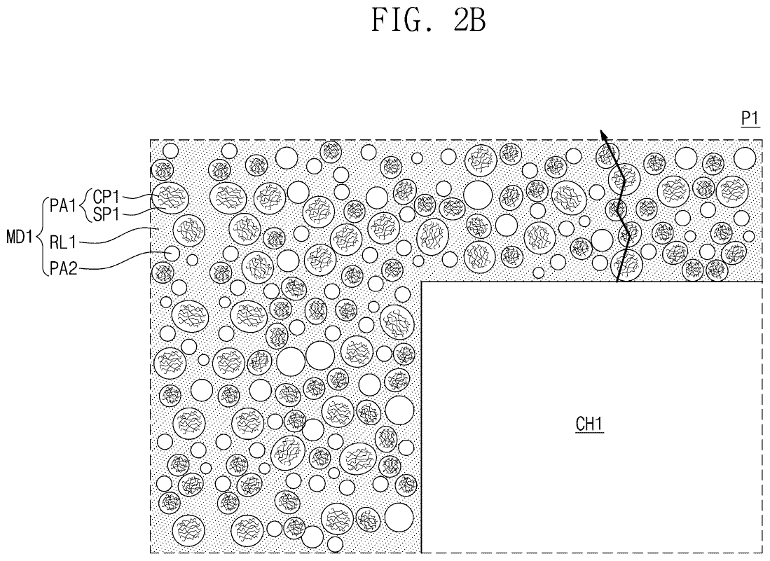

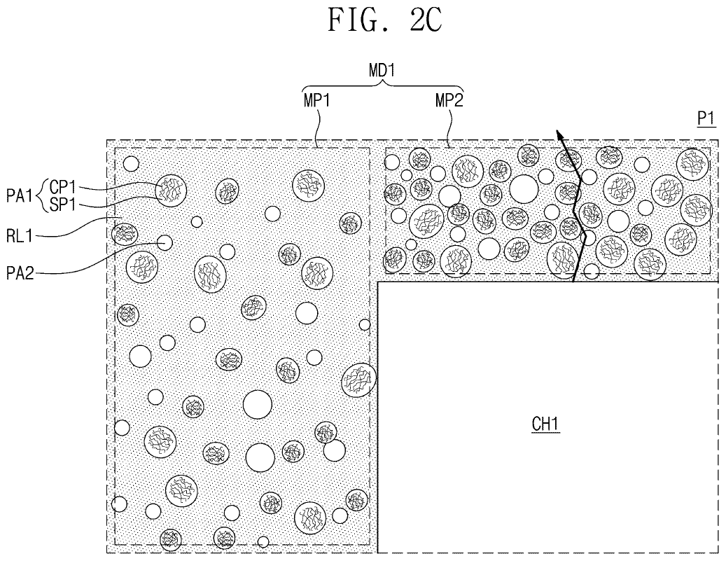

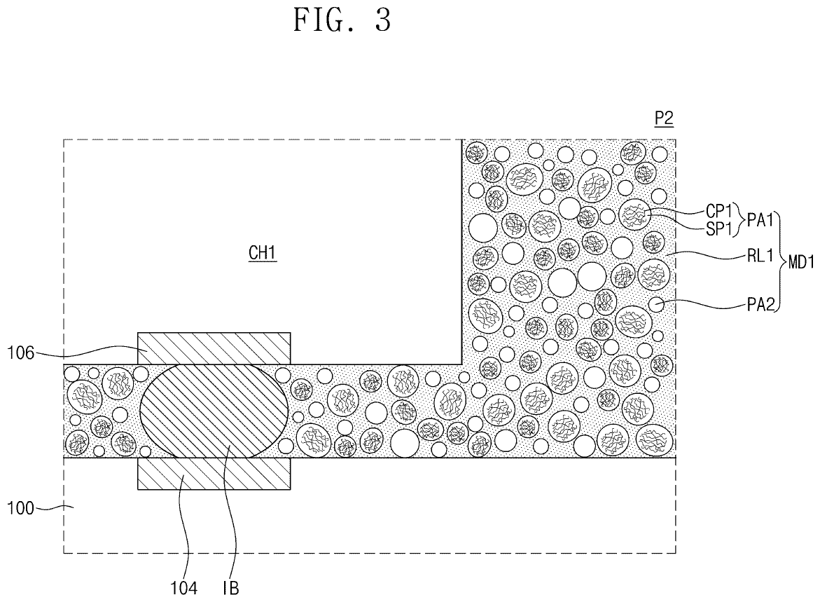

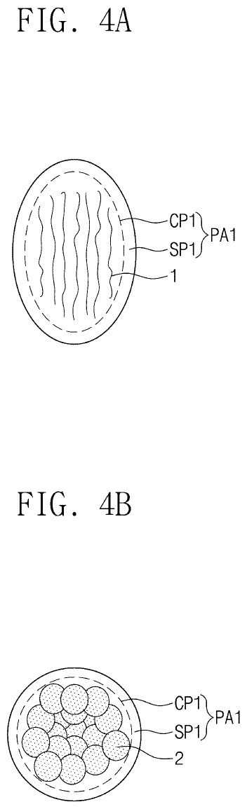

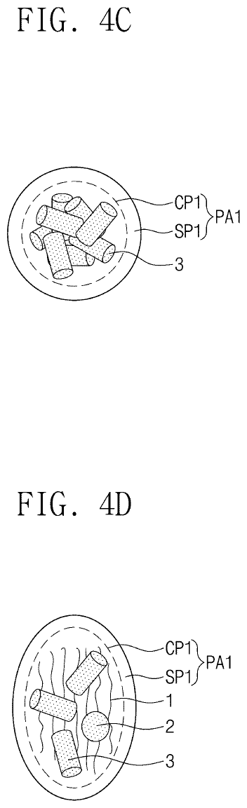

FIG. 1 is a cross-sectional view of a semiconductor package according to embodiments of the present disclosure. FIGS. 2A and 2B are enlarged diagrams of part ‘P1’ of FIG. 1 according to embodiments of the present disclosure. FIG. 3 is an enlarged diagram of part ‘P2’ of FIG. 1 according to embodiments of the present disclosure. FIGS. 4A to 4D are cross-sectional views of a filler particle according to embodiments of the present disclosure.

Referring to FIG. 1, a semiconductor package 1000 according to the present embodiment includes a package substrate 100, a first semiconductor device CH1 mounted on the same, a first mold layer MD1 covering the same. For example, the package substrate 100 may be a printed circuit board having both surfaces or a multiple layer. In one or more examples, the package substrate 100 may be a redistribution substrate. The package substrate 100 may include substrate upper pads 104 and substrate lower pads 102. The package substrate 100 may further include internal vias and internal wires connecting at least some of the substrate upper pads 104 to at least some of the substrate lower pads 102. The substrate lower pads 102 and the substrate upper pads 104 may include a conductive material such as copper, aluminum, nickel and gold.

External connection terminals OB may be bonded to the substrate lower pads 102 of the package substrate 100. For example, the external connection terminals OB may be one of a conductive bump, a conductive pillar and a solder ball. The external connection terminals OB may include at least one of copper or SnAg.

The first semiconductor device CH1 may be mounted on the package substrate 100 in accordance with a flip chip bonding method. In one or more examples, the flip chip bonding method may include interconnecting semiconductor devices to external circuitry with solder bumps deposited on chip pads. To mount the chip to external circuitry, the chip may be flipped over so that the a top side of the chip faces down and aligned so that the pads of the chip match the pads of the external circuit, where solder may be reflowed to complete the interconnect FIG. 1 illustrates that one first semiconductor device CH1 is mounted, but the present disclosure is not limited thereto. A plurality of first semiconductor devices CH1 may be horizontally mounted on an upper surface of the package substrate 100 and/or may be vertically stacked on the upper surface of the package substrate 100.

The first semiconductor device CH1 may be referred to as ‘a semiconductor chip’ or ‘a semiconductor die’. The first semiconductor device CH1 may be at least one selected from a system large scale integration (LSI) chip, a logic circuit chip, an image sensor chip such as a CMOS imaging sensor (CIS), a flash memory chip, a memory device chip such as a DRAM chip, an SRAM chip, an EEPROM chip, a PRAM chip, an MRAM chip, an ReRAM chip, a high bandwidth memory (HBM) chip, or a hybrid memory cubic (HMC) chip, a microelectromechanical system (MEMS) chip or an application specific integrated circuit (ASIC) chip. Chip pads 106 may be disposed on a lower surface of the first semiconductor device CH1. The chip pads 106 may include a conductive material such as copper, aluminum, nickel and gold.

The first semiconductor device CH1 may be connected to the package substrate 100 by using internal connection members IB. The internal connection members IB may be located between the first semiconductor device CH1 and the package substrate 100. The internal connection members IB may connect the chip pads 106 of the first semiconductor device CH1 to the substrate upper pads 104 of the package substrate 100. The internal connection members IB may be at least one of a solder ball, a conductive bump or a conductive pillar. The internal connection members IB may include at least one of copper, tin or lead.

The first mold layer MD1 may cover the first semiconductor device CH1 and the upper surface of the package substrate 100. The first mold layer MD1 may be interposed between the package substrate 100 and the first semiconductor device CH1, and may fill spaces between the internal connection members IB. The first mold layer MD1 may be formed of an epoxy mold compound (EMC). The EMC may include any suitable material such as epoxy resin, phenolic compounds, curing agent, fillers, etc. to safeguard electronic components.

A process of manufacturing the semiconductor package 1000 may include mounting the first semiconductor device CH1 on the package substrate 100, and forming the first mold layer MD1 covering the same. Forming the first mold layer MD1 may be performed by loading, in a die, the package substrate 100 on which the first semiconductor device CH1 is mounted, and then supplying and curing a mold composition in a liquid state, or supplying and melting, and then curing a mold composition provided in a solid film/sheet form. The mold composition may include a resin and first filler particles PA1. The mold composition may further include a curing agent and an additive.

Specifically, referring to FIG. 2A, the first mold layer MD1 may include a first resin layer RL1 and the first filler particles PA1. For example, the first resin layer RL1 may include, epoxy, epoxy acrylate, or a polymer material. For example, the polymer material may be polymethylmethacrylate (PMMA) or polyethylene terephthalate (PET). The first filler particles PA1 may have a diameter (or a width) of about 0.1 μm to about 100 μm. Each of the first filler particles PA1 may have a form of an ellipse or a sphere. In one or more examples, the filler particles PA1 may be mixture of particles that are both formed of ellipses and sphere. On and beside the first semiconductor device CH1, the first filler particles PA1 included in the first mold layer MD1 may have a diameter (or a width) of about 0.1 μm to about 100 μm. The first filler particles PA1 may be included as about 1% to about 95% of the total weight (or the total volume) of the first mold layer MD1. The first resin layer RL1 may be included as about 1% to about 30% of the total weight (or the total volume) of the first mold layer MD1.

Referring to FIG. 2A, and 4A to 4D, each of the first filler particles PA1 may include a first core portion CP1 and a first coating layer SP1 surrounding the same. Specifically, a diameter or a width of the first core portion CP1 may be about 1 nm to about 5 μm. The first core portion CP1 may include a carbon material. The carbon material may be one of graphene, carbon nanotube, diamond or graphite. The carbon material may be selected to improve a thermal conductivity of the first filler particles PA1. For example, as in FIG. 4A, the first core portion CP1 may include graphene sheet pieces 1. In one or more examples, as in FIG. 4B, the first core portion CP1 may have a form of a pellet composed of carbon nanoparticles 2. The carbon nanoparticles 2 may include one of graphene, carbon nanotube, diamond and graphite. In one or more examples, as in FIG. 4C, the first core portion CP1 may include carbon nanotubes 3. In one or more examples, as in FIG. 4D, the first core portion CP1 may have a form in which the graphene sheet pieces 1, the carbon nanoparticles 2 and the carbon nanotubes 3 are mixed.

The first coating layer SP1 may have a thickness of about 1 nm to about 100 μm. The first coating layer SP1 may include a carbon-excluded inorganic material. The carbon-excluded inorganic material may include at least one of silica, alumina, magnesium oxide or boron nitride. However, as understood by one of ordinary skill in the art, the embodiments are not limited to these materials and may include any suitable inorganic material known to one of ordinary skill in the art.

A material that constitutes the first core portion CP1 may have a greater thermal conductivity than a material that constitutes the first coating layer SP1. For example, graphene that constitutes the first core portion CP1 may have a thermal conductivity of about 4800 W/mK to about 5300 W/mK, carbon nanotube may have a thermal conductivity of about 3500 W/mK, diamond may have a thermal conductivity of about 2000 W/mK, and graphite may have a thermal conductivity of about 400 W/mK to about 2000 W/mK. However, silica that constitutes the first coating layer SP1 may have a thermal conductivity of about 1.5 W/mK, alumina may have a thermal conductivity of about 30 W/mK, magnesium oxide may have a thermal conductivity of about 30 W/mK, and boron nitride may have a thermal conductivity of about 400 W/mK.

Since the first core portions CP1 of the first filler particles PA1 included in the first mold layer MD1 according to the present disclosure are formed of a carbon material having an excellent thermal conductivity, heat generated by the first semiconductor device CH1 may be easily dissipated to the outside thereof as shown by an arrow in FIG. 2A. Accordingly, malfunctioning of the first semiconductor device CH1 may be prevented, and reliability may be improved.

As in FIGS. 1 and 3, the first mold layer MD1 may be partially interposed between the first semiconductor device CH1 and the package substrate 100. The first filler particles PA1 partially included in the first mold layer MD1 may have a diameter (or a width) of about 0.1 μm to about 100 μm. The material that constitutes the first coating layer SP1 may be more insulating than the material that constitutes the first core portion CP1. The material that constitutes the first coating layer SP1 may have a lower electrical conductivity than the material that constitutes the first core portion CP1. Accordingly, an electrical short between adjacent internal connection members IB may be prevented.

The material that constitutes the first core portion CP1 may have a Young's modulus or a hardness different from a Young's modulus or a hardness of the material that constitutes the first coating layer SP1. Accordingly, the total Young's modulus or the total hardness of the first filler particles PA1 may be appropriately controlled. Accordingly, an adhesive force between the first mold layer MD1 and the first semiconductor device CH1 and/or an adhesive force between the first mold layer MD1 and the package substrate 100 may be improved to suppress a peeling phenomenon, and to minimize warpage of the semiconductor package 1000. As a result, in the semiconductor package according to the present disclosure, the heat dissipation characteristics may be improved, the electrical short may be prevented, the peeling phenomenon may be suppressed, and the warpage may be minimized. Accordingly, the present disclosure may provide the semiconductor package with improved reliability.

Referring to FIGS. 2B, 2C and 3, the first mold layer MD1 may further include second filler particles PA2 dispersed in the first resin layer RL1. The second filler particles PA2 may be randomly mixed with the first filler particles PA1. A material that constitutes the second filler particles PA2 may be the same as or different from the material that constitutes the first coating layer SP1 of the first filler particles PA1. The second filler particles PA2 may not include the first core portions CP1 of the first filler particles PA1. The second filler particles PA2 may include a carbon-excluded inorganic material. The carbon-excluded inorganic material may include at least one of silica, alumina, magnesium oxide or boron nitride. The second filler particles PA2 may have a diameter (or a width) of about 0.1 μm to about 100 μm. Each of the second filler particles PA2 may have a form of an ellipse or a sphere. In one or more examples, the filler particles PA2 may be mixture of particles that are both formed of ellipses and sphere. The second filler particles PA2 may have a diameter of about 1 μm to about 100 μm on an upper potion or a sidewall of the first semiconductor device CH1. The second filler particles PA2 may have a maximum diameter of about 100 μm between the package substrate 100 and the first semiconductor device CH1. The second filler particles PA2 may be included as about 1% to about 95% of the total weight (or the total volume) of the first mold layer MD1. The second filler particles PA2 may be added in order to control a Young's modulus or a hardness of the entire first mold layer MD1.

As in FIGS. 2A and 2B, a density (or a number or a content of the first filler particles PA1 per unit volume) of the first filler particles PA1 in the first mold layer MD1 may be constant or similar regardless of a position. A density (or a number or a content of the second filler particles PA2 per unit volume) of the second filler particles PA2 in the first mold layer MD1 may be constant or similar regardless of a position.

In one or more examples, referring to FIG. 2C, the first mold layer MD1 includes a first mold part MP1 adjacent to the sidewall of the first semiconductor device CH1 and a second mold part MP2 adjacent to an upper surface of the first semiconductor device CH1. A density (or a number or a content of the first filler particles PA1 per unit volume) of the first filler particles PA1 in the second mold part MP2 may be greater than a density (or a number or a content of the first filler particles PA1 per unit volume) of the first filler particles PA1 in the first mold part MP1. Accordingly, heat generated by the upper portion of the first semiconductor device CH1 is easily dissipated to the outside thereof.

A density (or a number or a content of the second filler particles PA2 per unit volume) of the second filler particles PA2 in the second mold part MP2 may be greater than a density (or a number or a content of the second filler particles PA2 per unit volume) of the second filler particles PA2 in the first mold part MP1. Although FIG. 2C illustrates that the first mold part MP1 covers a side surface of the first semiconductor device CH1 and the second mold part MP2 covers an upper surface of the first semiconductor device CH1, the embodiments are not limited to this configuration. In one or more examples, the second mold part MP2 may cover at least a portion of the side surface of the first semiconductor device CH1. In one or more examples, the first mold part MP1 may cover at least a portion of the upper surface of the first semiconductor device CH1.

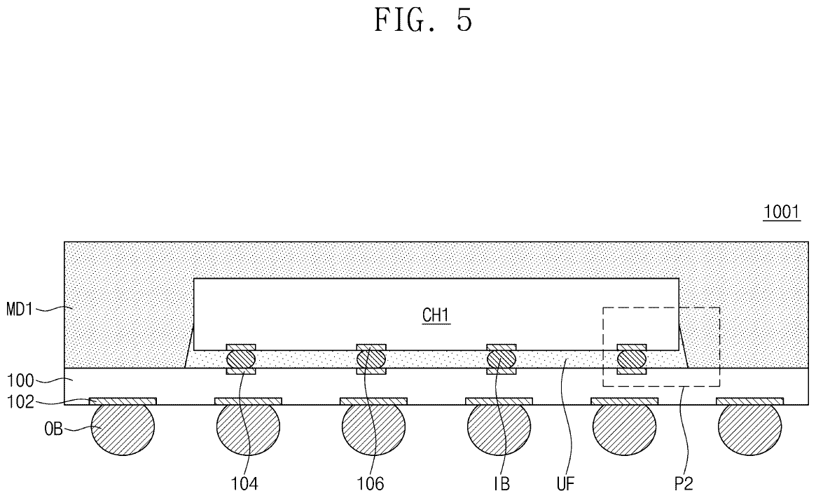

FIG. 5 is a cross-sectional view of the semiconductor package according to embodiments of the present disclosure.

Referring to FIG. 5, a semiconductor package 1001 according to the present embodiment may further include an underfill layer UF interposed between the first semiconductor device CH1 and the package substrate 100. The underfill layer UF may fill the spaces between the internal connection members IB. The underfill layer UF may enhance a mechanical strength of the semiconductor package 1001 and/or improve thermal performance of the semiconductor package 1001. A portion of the underfill layer UF may cover a lower sidewall of the first semiconductor device CH1. A sidewall of the underfill layer UF may be in contact with the first mold layer MD1. The first mold layer MD1 is not interposed between the package substrate 100 and the first semiconductor device CH1. A structure except for that may be the same as or similar to what is described with reference to FIG. 1. The underfill layer UF may be manufactured by adhering a non-conductive film (NCF), or injecting and then curing an underfill composition between the package substrate 100 and the first semiconductor device CH1.

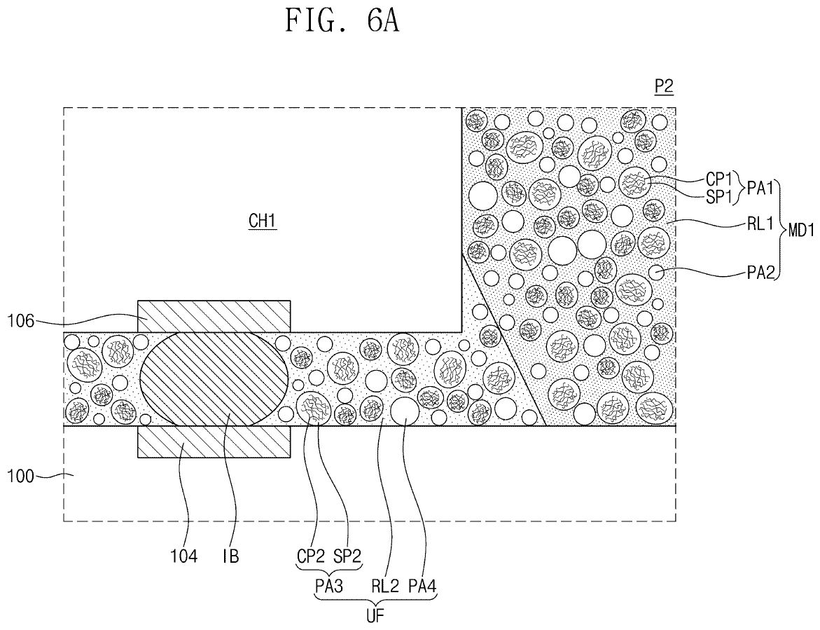

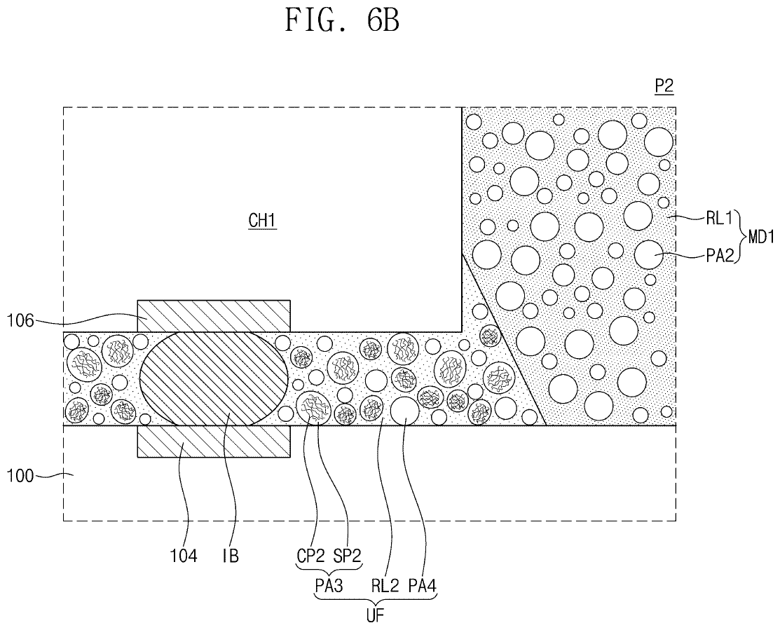

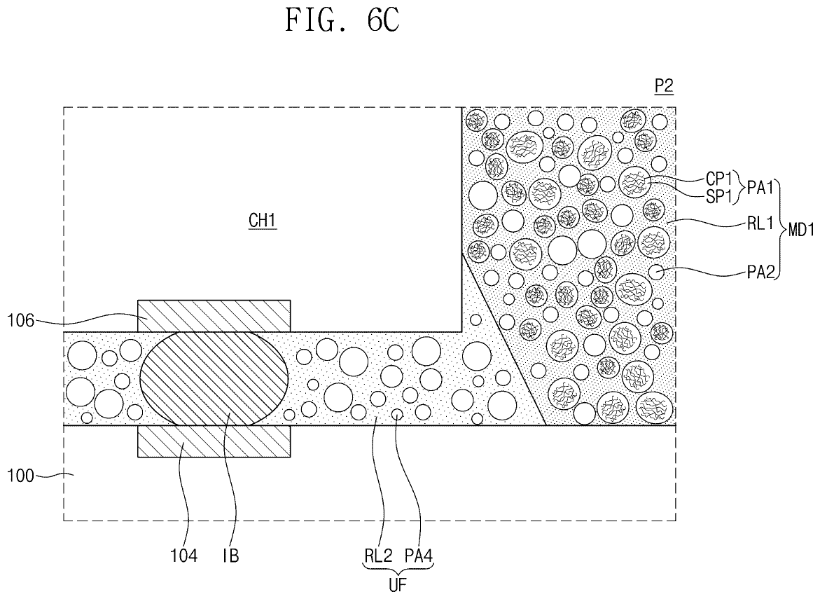

FIGS. 6A to 6C are enlarged diagrams of part ‘P2’ of FIG. 5 according to embodiments of the present disclosure.

Referring to FIG. 6A, the first mold layer MD1 may be the same as or similar to what is described with reference to FIGS. 2A to 2C. The underfill layer UF may include third filler particles PA3 and a second resin layer RL2. The second resin layer RL2 may be the same as or different from the first resin layer RL1 of the first mold layer MD1. The second resin layer RL2 may include a thermosetting resin, a light-curable resin, epoxy, epoxy acrylate, or a polymer material. For example, the polymer material may be polymethylmethacrylate (PMMA) or polyethylene terephthalate (PET). The third filler particles PA3 may have a diameter (or a width) of about 0.1 μm to about 100 μm. Each of the third filler particles PA3 may have a form of an ellipse or a sphere. In one or more examples, the third filler particles PA3 may be mixture of particles that are both formed of ellipses and sphere. The third filler particles PA3 may have a diameter (or a width) of about 0.1 μm to about 100 μm. The third filler particles PA3 may be included as about 1% to about 95% of the total weight (or the total volume) of the underfill layer UF. The second resin layer RL2 may be included as about 1% to about 30% of the total weight (or the total volume) of the underfill layer UF.

Each of the third filler particles PA3 may include a second core portion CP2 and a second coating layer SP2 surrounding the same. Specifically, the second core portion CP2 may have a diameter or a width of about 1 nm to about 5 μm. The second core portion CP2 may include a carbon material. The carbon material may be one of graphene, carbon nanotube, diamond and graphite. The carbon material that constitutes the second core portion CP2 may be the same as or different from the carbon material that constitutes the first core portion CP1. A structure of the second core portion CP2 may correspond to any one of structure of the first core portion CP1 of FIGS. 4A to 4D.

The second coating layer SP2 may have a thickness of about 1 nm to about 100 μm. The second coating layer SP2 may include a carbon-excluded inorganic material. The carbon-excluded inorganic material may include at least one of silica, alumina, magnesium oxide or boron nitride. The second coating layer SP2 may include the same material as or a different material from that of the first coating layer SP1.

A material that constitutes the second core portion CP2 may have a greater thermal conductivity than a material that constitutes the second coating layer SP2. The material that constitutes the second coating layer SP2 may be more insulating than the material that constitutes the second core portion CP2. The material that constitutes the second coating layer SP2 may have a lower electrical conductivity than the material that constitutes the second core portion CP2. The material that constitutes the second core portion CP2 may have a Young's modulus or a hardness different from that of the material that constitutes the second coating layer SP2.

Since the second core portion CP2 of the third filler particles PA3 included in the underfill layer UF according to the present embodiment is formed of the carbon material having an excellent thermal conductivity, heat generated by the first semiconductor device CH1 may be easily dissipated to the lower portions thereof. Accordingly, malfunctioning of the first semiconductor device CH1 may be prevented and reliability may be improved.

The underfill layer UF may further include fourth filler particles PA4 dispersed in the second resin layer RL2. The fourth filler particles PA4 may be randomly mixed with the third filler particles PA3. The fourth filler particles PA4 may have a smaller maximum size than the second filler particles PA2. The fourth filler particles PA4 may include the same material as or a different material from the second filler particles PA2. The fourth filler particles PA4 may include a carbon-excluded inorganic material. The carbon-excluded inorganic material may include at least one of silica, alumina, magnesium oxide or boron nitride.

The fourth filler particles PA4 may be added in order to control a Young's modulus or a hardness of the entire underfill layer UF. Accordingly, an adhesive force between the underfill layer UF and the first semiconductor device CH1 and/or an adhesive force between the underfill layer UF and the package substrate 100 may be improved to suppress a peeling phenomenon, and to minimize warpage of the semiconductor package 1001.

Referring to FIG. 6B, in the semiconductor package according to the present embodiment, the first mold layer MD1 may include the first resin layer RL1 and the second filler particles PA2, but may exclude the first filler particles PA1. A structure except for that may be the same as that in FIG. 6A.

Referring to FIG. 6C, in the semiconductor device according to the present embodiment, the underfill layer UF may include the second resin layer RL2 and the fourth filler particles PA4, but may exclude the third filler particles PA3.

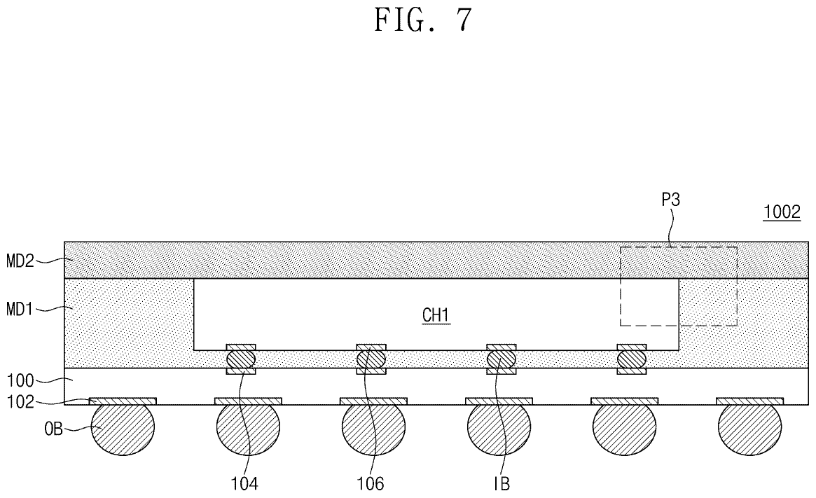

FIG. 7 is a cross-sectional view of the semiconductor package according to embodiments of the present disclosure.

Referring to FIG. 7, a semiconductor package 1002 according to the present embodiment includes the first mold layer MD1 covering the side surfaces of the first semiconductor device CH1 and a second mold layer MD2 covering the upper surface of the first semiconductor device CH1. The upper surface of the first mold layer MD1 may be coplanar with the upper surface of the first semiconductor device CH1. The first mold layer MD1 may be interposed between the first semiconductor device CH1 and the package substrate 100. The second mold layer MD2 may cover the upper surface of the first mold layer MD1. A structure except for that may be the same as or similar to what is described with reference to FIG. 1.

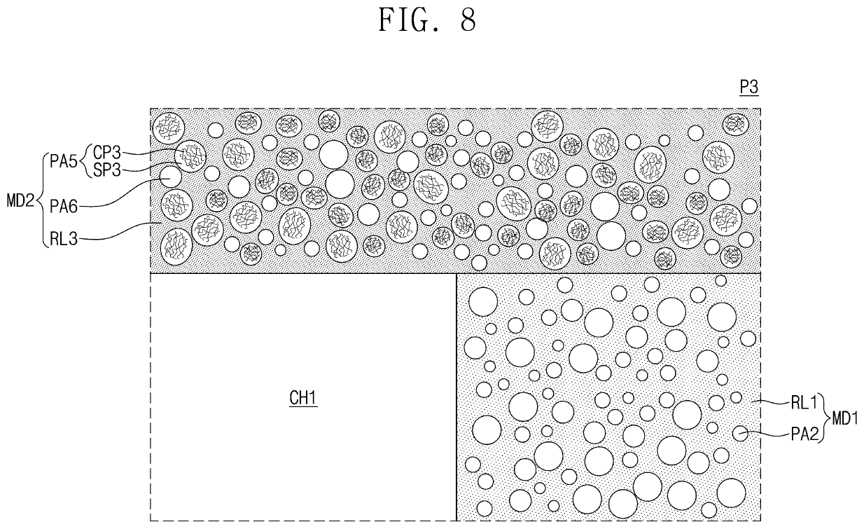

FIG. 8 is an enlarged diagram of part ‘P3’ of FIG. 7 according to embodiments of the present disclosure.

Referring to FIG. 8, the first mold layer MD1 may include the first resin layer RL1 and the second filler particles PA2 of FIG. 2B, but may exclude the first filler particles PA1. The second mold layer MD2 may include a third resin layer RL3 and fifth filler particles PA5. The third resin layer RL3 may be formed of the same material as or a different material from the first resin layer RL1. The third resin layer RL3 may include epoxy, epoxy acrylate or a polymer material. For example, the polymer material may be polymethylmethacrylate (PMMA) or polyethylene terephthalate (PET). The fifth filler particles PA5 may have a diameter (or a width) of about 0.1 μm to about 100 μm. Each of the fifth filler particles PA5 may have a form of an ellipse or a sphere. In one or more examples, the fifth filler particles PA5 may be mixture of particles that are both formed of ellipses and sphere. The fifth filler particles PA5 may have a diameter (or a width) of about 0.1 μm to about 100 μm. The fifth filler particles PA5 may be included as about 1% to about 95% of the total weight (or the total volume) of the second mold layer MD2. The third resin layer RL3 may be included as about 1% to about 30% of the total weight (or the total volume) of the second mold layer MD2.

Each of the fifth filler particles PA5 may include a third core portion CP3 and a third coating layer SP3 surrounding the same. Specifically, the third core portion CP3 may have a diameter or a width of about 1 nm to about 5 μm. The third core portion CP3 may include a carbon material. The carbon material may be one of graphene, carbon nanotube, diamond and graphite. A structure of the third core portion CP3 may correspond to any one of structures of the first core portion CP1 of FIGS. 4A to 4D.

The third coating layer SP3 may have a thickness of about 1 nm to about 100 μm. The third coating layer SP3 may include a carbon-excluded inorganic material. The carbon-excluded inorganic material may include at least one of silica, alumina, magnesium oxide or boron nitride.

A material that constitutes the third core portion CP3 may have a greater thermal conductivity than a material that constitutes the third coating layer SP3. The material that constitutes the third coating layer SP3 may be more insulating than the material that constitutes the third core portion CP3. The material that constitutes the third coating layer SP3 may have a lower electrical conductivity than the material that constitutes the third core portion CP3. The material that constitutes the third core portion CP3 may have a Young's modulus or a hardness different from that of the material that constitutes the third coating layer SP3.

Since the third core portion CP3 of the fifth filler particles PA5 included in the second mold layer MD2 according to the present embodiment is formed of the carbon material having an excellent thermal conductivity, heat generated by the first semiconductor device CH1 may be easily dissipated to the outside thereof. Accordingly, malfunctioning of the first semiconductor device CH1 may be prevented and reliability may be improved.

The second mold layer MD2 may further include sixth filler particles PA6 dispersed in the third resin layer RL3. The sixth filler particles PA6 may be randomly mixed with the fifth filler particles PA5. The sixth filler particles PA6 may include the same material as or a different material from the second filler particles PA2. The sixth filler particles PA6 may include a carbon-excluded inorganic material. The carbon-excluded inorganic material may include at least one of silica, alumina, magnesium oxide or boron nitride. The sixth filler particles PA6 may be added in order to control a Young's modulus or a hardness of the entire second mold layer MD2.

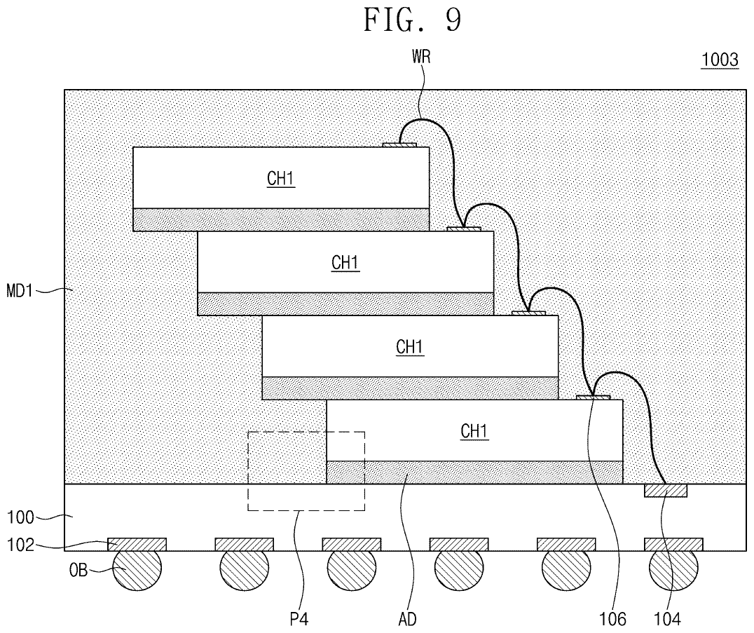

FIG. 9 is a cross-sectional view of the semiconductor package according to embodiments of the present disclosure.

Referring to FIG. 9, a semiconductor package 1003 according to the present embodiment includes the package substrate 100, the first semiconductor devices CH1 and the first mold layer MD1. The first semiconductor devices CH1 may be stacked on the package substrate 100. End portions of the first semiconductor devices CH1 may have a step form. The chip pads 106 may be respectively disposed on upper portions of the first semiconductor devices CH1. Wires WR may connect the chip pads 106 of the first semiconductor devices CH1 to the substrate upper pads 104. The wires WR may include gold or copper. Adhesive layers AD may be respectively interposed between the first semiconductor devices CH1. The adhesive layer AD may be interposed between the package substrate 100 and a lowermost first semiconductor device CH1. The adhesive layer AD may be a die attach film (DAF). The first mold layer MD1 may cover the first semiconductor devices CH1, the package substrate 100 and the wires WR, and may be in contact with side surfaces and some portions of lower surfaces of the adhesive layers AD.

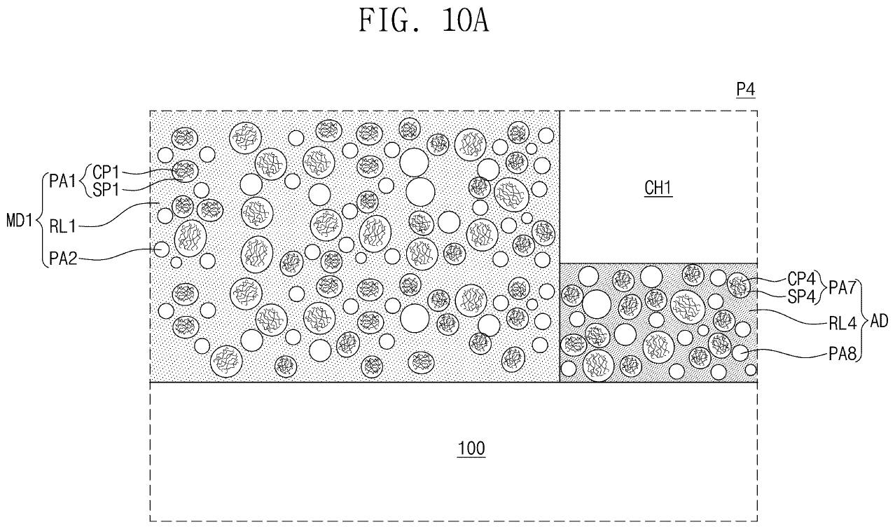

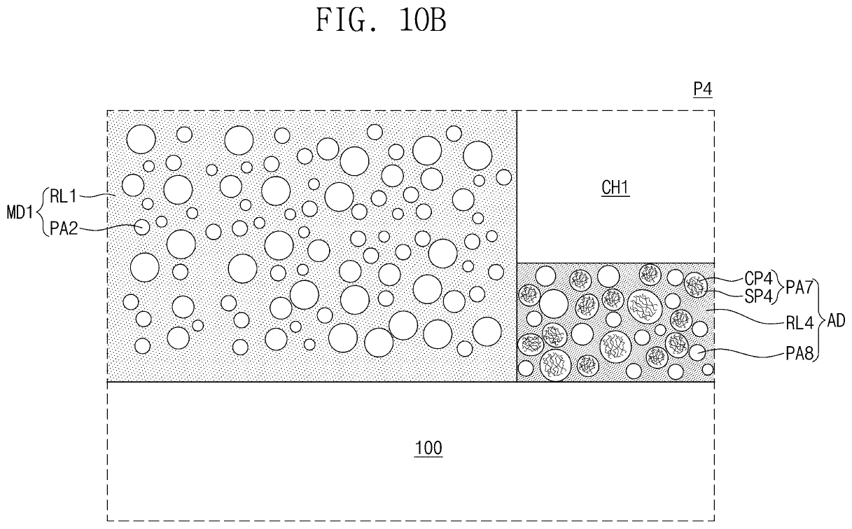

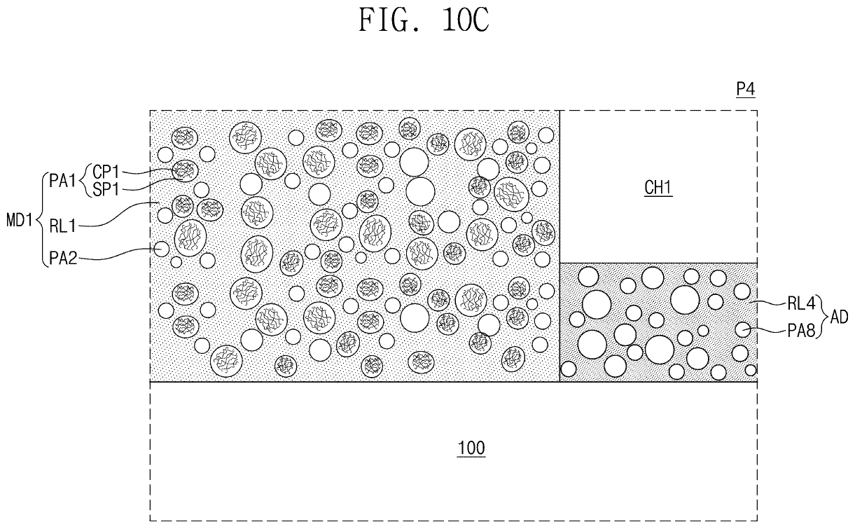

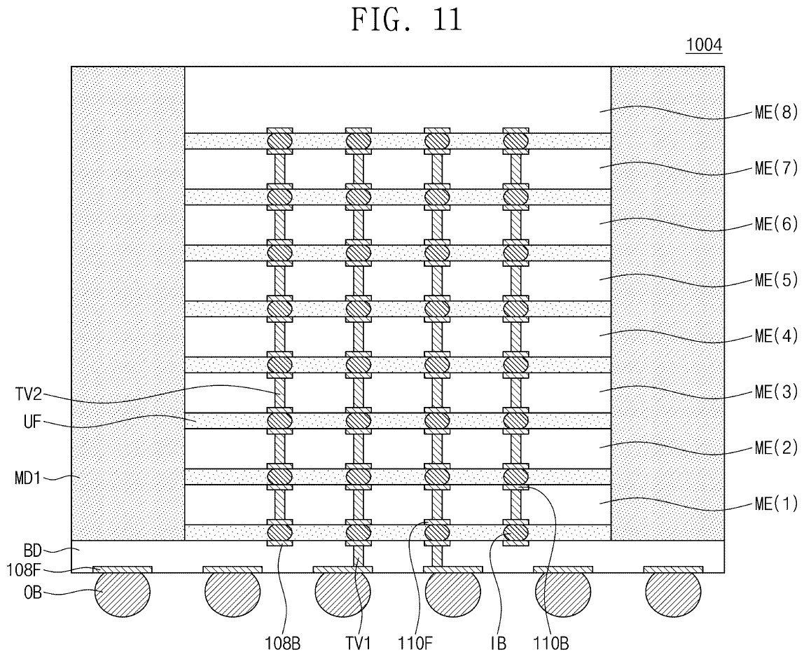

FIGS. 10A to 10C are enlarged diagrams of part ‘P4’ of FIG. 9 according to embodiments of the present disclosure.

Referring to FIG. 10A, the first mold layer MD1 may be the same as or similar to what is described with reference to FIGS. 2A to 2C. The adhesive layer AD may include a fourth resin layer RL4 and seventh filler particles PA7. The fourth resin layer RL4 may be the same as or different from the first resin layer RL1 of the first mold layer MD1. The fourth resin layer RL4 may include a thermosetting resin, a light-curable resin, epoxy, epoxy acrylate, or a polymer material. For example, the polymer material may be polymethylmethacrylate (PMMA) or polyethylene terephthalate (PET). The seventh filler particles PA7 may have a diameter (or a width) of about 0.1 μm to about 100 μm. Each of the seventh filler particles PA7 may have a form of an ellipse or a sphere. In one or more examples, the seventh filler particles PA7 may be mixture of particles that are both formed of ellipses and sphere. The seventh filler particles PA7 may have a diameter (or a width) of about 0.1 μm to about 100 μm. The seventh filler particles PA7 may be included as about 1% to about 95% of the total weight (or the total volume) of the underfill layer UF. The second resin layer RL2 may be included as about 1% to about 30% of the total weight (or the total volume) of the adhesive layer AD.

Each of the seventh filler particles PA7 may include a fourth core portion CP4 and a fourth coating layer SP4 surrounding the same. Specifically, the fourth core portion CP4 may have a diameter or a width of about 1 nm to about 5 μm. The fourth core portion CP4 may include a carbon material. The carbon material may be one of graphene, carbon nanotube, diamond and graphite. A carbon material that constitutes the fourth core portion CP4 may be the same as or different from a carbon material that constitutes the first core portion CP1. A structure of the fourth core portion CP4 may correspond to any one of the structures of the first core portion CP1 of FIGS. 4A to 4D.

The fourth coating layer SP4 may have a thickness of about 1 nm to about 100 μm. The fourth coating layer SP4 may include a carbon-excluded inorganic material. The carbon-excluded inorganic material may include at least one of silica, alumina, magnesium oxide or boron nitride. The fourth coating layer SP4 may include the same material as or a different material from the first coating layer SP1.

A material that constitutes the fourth core portion CP4 may have a greater thermal conductivity than a material that constitutes the fourth coating layer SP4. The material that constitutes the fourth coating layer SP4 may be more insulating than the material that constitutes the fourth core portion CP4. The material that constitutes the fourth coating layer SP4 may have a lower electrical conductivity than the material that constitutes the fourth core portion CP4. The material that constitutes the fourth core portion CP4 may have a Young's modulus or a hardness different from that of the material that constitutes the second coating layer SP2.

Since the fourth core portion CP4 of the seventh filler particles PA7 included in the adhesive layer AD according to the present embodiment is formed of the carbon material having an excellent thermal conductivity like the above, heat generated by the first semiconductor devices CH1 may be easily dissipated to the lower portions thereof. Accordingly, malfunctioning of the first semiconductor devices CH1 may be prevented and reliability may be improved.

The adhesive layer AD may further include eighth filler particles PA8 dispersed in the fourth resin layer RL4. The eighth filler particles PA8 may be randomly mixed with the seventh filler particles PA7. The eighth filler particles PA8 may have a smaller maximum size than the first filler particles PA1. The eighth filler particles PA8 may include the same material as or a different material from the second filler particles PA2. The eighth filler particles PA8 may include a carbon-excluded inorganic material. The carbon-excluded inorganic material may include at least one of silica, alumina, magnesium oxide or boron nitride.

The eighth filler particles PA8 may be added in order to control a Young's modulus or a hardness of the entire adhesive layer AD. Accordingly, an adhesive force between the adhesive layer AD and the first semiconductor device CH1 and/or an adhesive force between the adhesive layer AD and the package substrate 100 may be improved to suppress a peeling phenomenon, and to minimize warpage of the semiconductor package 1003.

In one or more examples, referring to FIG. 10B, in the semiconductor package according to the present embodiment, the first mold layer MD1 may include the first resin layer RL1 and the second filler particles PA2, but may exclude the first filler particles PA1. A structure except for that may be the same as that in FIG. 10A.

In one or more examples, referring to FIG. 10C, in the semiconductor package according to the present embodiment, the adhesive layer AD may include the fourth resin layer RL4 and the eighth filler particles PA8, but may exclude the seventh filler particles PA7. A structure except for that may be the same as that in FIG. 10A.

FIG. 11 is a cross-sectional view of the semiconductor package according to embodiments of the present disclosure.

Referring to FIG. 11, a semiconductor package 1004 according to the present embodiment includes a buffer die BD, memory dies ME and the first mold layer MD1. The buffer die BD may include first front surface die pads 108F, first rear surface die pads 108B and first penetration vias TV. The first penetration vias TV may connect some of the first front surface die pads 108F to some of the first rear surface die pads 108B. The buffer die BD may further include a first semiconductor substrate and first integrated circuits disposed on a front surface thereof. The buffer die BD may perform input/output/operation of a data. The external connection terminals OB may be bonded to the first front surface die pads 108F.

The memory dies ME may be stacked on the buffer die BD. The memory dies ME may store a data. The memory dies ME may be the same memory chip as each other. For example, the memory chip may be DRAM, SRAM, MRAM, PRAM, RRAM or NAND flash. According to FIG. 11, it is illustrated that eight memory dies ME(1) to ME(8) are stacked, but a number of the memory dies ME is not limited to FIG. 11, and may be various. For example, the semiconductor package 1004 may be a high bandwidth memory (HBM) chip. Except for the eighth memory die ME(8) located at an uppermost level, each of the first to seventh memory dies ME(1) to ME(7) may include second die front surface pads 110F, second die rear surface pads 110B and second penetration vias TV2. The eighth memory die ME(8) may include the second die front surface pads 110F, but may exclude the second die rear surface pads 110B and the second penetration vias TV2. The memory dies ME may further include a second semiconductor substrate and second integrated circuits disposed on a front surface thereof.

The underfill layer UF is interposed between the memory dies ME, and between the first memory die ME(1) and the buffer die BD. Side surfaces of the memory dies ME, side surfaces of the underfill layers UF and an upper surface of the buffer die BD may be covered with the first mold layer MD1. The first mold layer MD1 and the underfill layer UF may be the same as or similar to what is described with reference to FIGS. 6A to 6C.

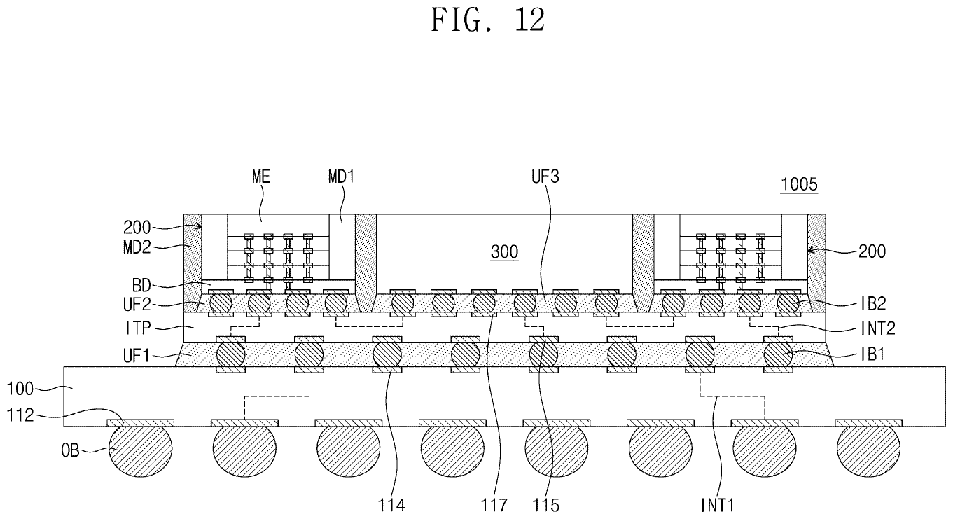

FIG. 12 is a cross-sectional view of the semiconductor package according to embodiments of the present disclosure.

Referring to FIG. 12, a semiconductor package 1005 according to the present embodiment includes the package substrate 100, an interposer substrate ITP, first semiconductor chips 200, a second semiconductor chip 300 and the second mold layer MD2. For example, the package substrate 100 may be a printed circuit board having both surfaces or a multiple layer. In one or more examples, the package substrate 100 may be a redistribution substrate. The package substrate 100 may include first substrate upper pads 114 and first substrate lower pads 112. The package substrate 100 may further include first internal wires INT1 connecting at least some of the first substrate upper pads 114 to at least some of the first substrate lower pads 112.

The interposer substrate ITP may be a semiconductor die or a printed circuit board having both surfaces or a multiple layer. The interposer substrate ITP may include second substrate upper pads 117 and second substrate lower pads 115 and second internal wires INT2. The interposer substrate ITP may be connected to the package substrate 100 by first internal connection members IB1. A first underfill layer UF1 may be interposed between the interposer substrate ITP and the package substrate 100.

Second internal connection members IB2 may be interposed on the interposer substrate ITP to mount the first semiconductor chips 200 and the second semiconductor chip 300. The first semiconductor chips 200 may have the same structure as or a similar structure to the semiconductor package (that is, the high bandwidth memory (HBM) chip) described with reference to FIG. 11. The first semiconductor chips 200 may be spaced apart from each other with the second semiconductor chip 300 therebetween. The second semiconductor chip 300 may be a logic chip, a processor chip or an application specific integrated circuit (ASIC) chip. A second underfill layer UF2 may be interposed between the first semiconductor chips 200 and the interposer substrate ITP. A third underfill layer UF3 may be interposed between the second semiconductor chip 300 and the interposer substrate ITP. The second mold layer MD2 may cover side surfaces of the second semiconductor chip 300 and the first semiconductor chips 200.

The second mold layer MD2 may include filler particles identical to or different from those of the first mold layer MD1 of the first semiconductor chips 200. The second mold layer MD2 may be the same as the second mold layer MD2 described with reference to FIG. 8. At least one of the first to third underfill layers UF1 to UF3 may be the same as the underfill layer UF described with reference to FIGS. 6A to 6C. A structure except for that may be the same as or similar to what is described above.

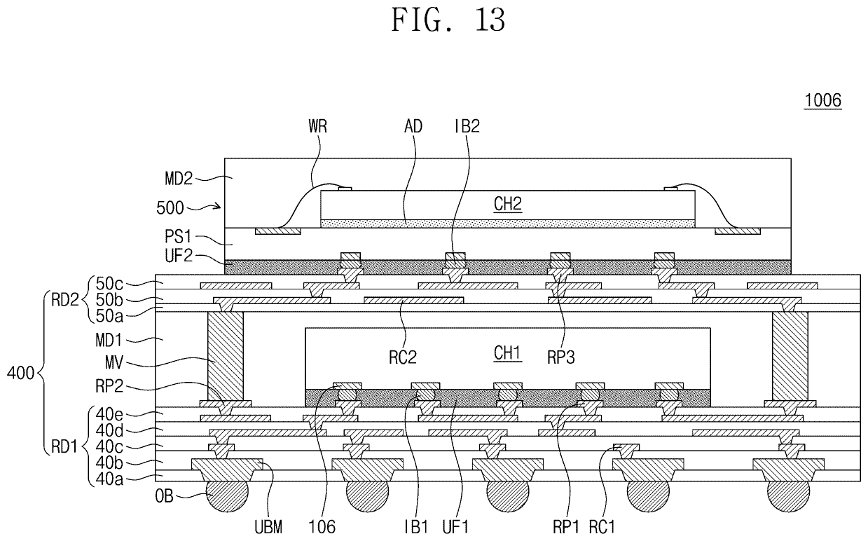

FIG. 13 is a cross-sectional view of the semiconductor package according to embodiments of the present disclosure.

Referring to FIG. 13, a semiconductor package 1006 according to the present embodiment may have a package-on-package structure including a first sub semiconductor package 400 and a second sub semiconductor package 500 mounted thereon.

The first sub semiconductor package 400 includes a first substrate RD1, the first semiconductor device CH1, the first mold layer MD1, a second substrate RD2, the first underfill layer UF1 and mold vias MV. The first substrate RD1 includes first insulating layers 40a to 40e, under bumps UBM, first substrate internal patterns RC1 and first and second conductive pads RP1 and RP2. Preferably, the first insulating layers 40a to 40e may be photo-imageable dielectric (PID).

Each of the under bumps UBM, the first substrate internal patterns RC1, the first and second conductive pads RP1 and RP2 may be formed of a conductive material. Each of the under bumps UBM, the first substrate internal patterns RC1 and the first and second conductive pads RP1 and RP2 may include at least one metal of titanium, titanium nitride, tantalum, tantalum nitride, copper, aluminum, nickel, or gold.

The under bumps UBM may penetrate a lowermost first insulating layer 40a among the first insulating layers 40a to 40e. The external connection terminals OB may be bonded to the under bumps UBM. For example, the external connection terminals OB may be at least one of a solder ball, a conductive bump or a conductive pillar. For example, the external connection terminals OB may include at least one of tin, nickel, silver, copper, aluminum, or gold.

The first substrate internal patterns RC1 may be interposed between the first insulating layers 40a to 40e, and may partially penetrate the same. The first and second conductive pads RP1 and RP2 may be located on an uppermost first insulating layer 40e among the first insulating layers 40a to 40e, and may penetrate the uppermost first insulating layer 40e.

The second substrate RD2 may include second insulating layers 50a to 50c, second substrate internal patterns RC2 and third conductive pads RP3. Preferably, the second insulating layers 50a to 50c may be each the photo-imageable dielectric (PID). Each of the second substrate internal patterns RC2 and the third conductive pads RP3 may be formed of a conductive material. Each of the second substrate internal patterns RC2 and the third conductive pads RP3 may include at least one of titanium, titanium nitride, tantalum, tantalum nitride, copper, aluminum, nickel, or gold.

Each of the first substrate internal patterns RC1 and the second substrate internal patterns RC2 may include a diffusion-preventive layer and a wiring portion. The diffusion-preventive layer may cover a lower surface of the wiring portion. The diffusion-preventive layer may include at least one of titanium, titanium nitride, tantalum, or tantalum nitride. The wiring portion may include metal such as copper, aluminum, nickel and gold. Each of the first substrate internal patterns RC1 and the second substrate internal patterns RC2 may include a via portion penetrating one among the first insulating layers 40a to 40e and the second insulating layers 50a to 50c, and a line portion and a pad portion thereon. A width of the via portion may become narrower in a downward direction.

The first semiconductor device CH1 may be referred to as a semiconductor chip or a semiconductor die. The chip pads 106 may be disposed on a lower end of the first semiconductor device CH1.

The first internal connection members IB1 may be interposed between the chip pads 106 and the first conductive pads RP1, and may connect the same. For example, the first internal connection members IB1 may be at least one of a solder ball, a conductive bump or a conductive pillar. For example, the first internal connection members IB1 may include at least one of tin, nickel, silver, copper, gold or aluminum.

The first underfill layer UF1 may be interposed between the first semiconductor device CH1 and the first substrate RD1. Each of the mold vias MV may penetrate the first mold layer MD1. The mold vias MV may electrically connect the first substrate RD1 to the second substrate RD2. Each of the mold vias MV may be formed of copper. The mold vias MV may be in contact with the second conductive pads RP2.

The second sub semiconductor package 500 may interpose the second internal connection members IB2 to be bonded to the third conductive pads RP3 of the second substrate RD2 of the first sub semiconductor package 400. The second sub semiconductor package 500 may include a first sub package substrate PS1, a second semiconductor device CH2 disposed thereon, the adhesive layer AD interposed therebetween, the second mold layer MD2 covering the same, and the wires WR connecting the first sub package substrate PS1 and the second semiconductor device CH2. The first sub package substrate PS1 may be a printed circuit board having both surfaces or a multiple layer. In one or more examples, the first sub package substrate PS1 may be another redistribution substrate. For example, the second semiconductor device CH2 may be one selected from an image sensor chip such as a CMOS imaging sensor (CIS), a flash memory chip, a memory device chip such as a DRAM chip, an SRAM chip, an EEPROM chip, a PRAM chip, an MRAM chip, an ReRAM chip, a high bandwidth memory (HBM) chip, or a hybrid memory cubic (HMC) chip, a microelectromechanical system (MEMS) device chip or an application specific integrated circuit (ASIC) chip. The second underfill layer UF2 may be interposed between the first sub semiconductor package 400 and the second sub semiconductor package 500.

The second mold layer MD2 may include filler particles identical to or different from the first mold layer MD1. At least one of the first mold layer MD1 or the second mold layer MD2 may be the same as the first mold layer MD1 described with reference to FIGS. 2A to 2C. At least one of the first underfill layer UF1 or the second underfill layer UF2 may be the same as one of the underfill layers UF described with reference to FIGS. 6A to 6C. The adhesive layer AD may be the same as one of the adhesive layers AD described with reference to FIGS. 10A to 10C. A structure except for that may be the same as or similar to what is described above.

In a semiconductor package according to the present disclosure, heat dissipation characteristics may be improved, an electrical short may be prevented, and a peeling phenomenon may be suppressed to minimize warpage. Accordingly, the present disclosure may provide the semiconductor package with improved reliability.

Although the embodiments of the present invention have been described, it is understood that the present invention should not be limited to these embodiments but various changes and modifications can be made by one ordinary skilled in the art within the spirit and scope of the present invention as hereinafter claimed. Therefore, it should be understood that the embodiments described above are exemplary in all respects and are not intended to be limiting. Embodiments of FIGS. 1 to 13 may be combined with each other.

What is claimed is:

1. A semiconductor package comprising:
a substrate;
a semiconductor device on the substrate; and
a first mold layer on a first surface of the semiconductor device and a surface of the substrate,
wherein the first mold layer comprises a first resin layer and first filler particles in the first resin layer,
wherein at least one of the first filler particles comprises a first core portion and a first coating layer surrounding at least a portion of the first core portion,
wherein the first core portion comprises a carbon material, and
wherein the first coating layer comprises a carbon-excluded inorganic material.

2. The semiconductor package of claim 1, wherein the carbon material comprises at least one of graphene, carbon nanotube, diamond or graphite, and
wherein the carbon-excluded inorganic material comprises at least one of silica, alumina, magnesium oxide, or boron nitride.

3. The semiconductor package of claim 1, further comprising one or more internal connection members between the semiconductor device and the substrate, and configured to connect the semiconductor device and the substrate,
wherein the first filler particles are interposed between the semiconductor device and the substrate and between the one or more internal connection members.

4. The semiconductor package of claim 1, wherein the first mold layer further comprises second filler particles in the first resin layer,
wherein the second filler particles have a structure of a single layer or a structure of multiple layers, and
wherein the second filler particles comprise at least one of at least one of silica, alumina, magnesium oxide, or boron nitride.

5. The semiconductor package of claim 1, further comprising:
at least two internal connection members between the semiconductor device and the substrate, and configured to connect the semiconductor device to the substrate; and
an underfill layer between the semiconductor device and the substrate, and configured to fill spaces between the at least two internal connection members,
wherein the underfill layer comprises a second resin layer and second filler particles in the second resin layer.

6. The semiconductor package of claim 5, wherein each of the second filler particles comprises a second core portion and a second coating layer surrounding at least a portion of the second core portion,
wherein the second core portion comprises at least one of graphene, carbon nanotube, diamond, or graphite,
wherein the second coating layer has a structure of a single layer or a structure of multiple layers, and
wherein the second coating layer comprises at least one of silica, alumina, magnesium oxide, or boron nitride.

7. The semiconductor package of claim 1, further comprising an adhesive layer between the semiconductor device and the substrate,
wherein the adhesive layer comprises a second resin layer and second filler particles in the second resin layer.

8. The semiconductor package of claim 7, wherein each of the second filler particles comprises a second core portion and a second coating layer surrounding at least a portion of the second core portion,
wherein the second core portion comprises at least one of graphene, carbon nanotube, diamond, or graphite,
wherein the second coating layer has a structure of a single layer or a structure of multiple layers, and
wherein the second coating layer comprises at least one of silica, alumina, magnesium oxide or boron nitride.

9. The semiconductor package of claim 1, further comprising a second mold layer on the first mold layer and a second surface of the semiconductor device,
wherein the second mold layer comprises a second resin layer and second filler particles dispersed in the second resin layer,
wherein each of the second filler particles comprises a second core portion and a second coating layer surrounding at least a portion of the second core portion,
wherein the second core portion comprises at least one of graphene, carbon nanotube, diamond, or graphite,
wherein the second coating layer has a structure of a single layer or a structure of multiple layers,
wherein the second coating layer comprises at least one of silica, alumina, magnesium oxide, or boron nitride, and
wherein a number of the second filler particles per unit area in the second mold layer is greater than a number of the first filler particles per unit area in the first mold layer.

10. The semiconductor package of claim 1, wherein the first mold layer extends to be on the surface of the semiconductor device,
wherein the first mold layer comprises a first mold part on the surface of the semiconductor device and a second mold part on the first surface of the semiconductor device, and
wherein a number of the first filler particles per unit area in the first mold part is greater than a number of the first filler particles per unit area in the second mold part.

11. The semiconductor package of claim 1, wherein the first filler particles are about 10% to about 95% of a total weight of the first mold layer.

12. The semiconductor package of claim 1, wherein at least one of the first filler particles have a diameter of about 0.1 μm to about 100 μm.

13. The semiconductor package of claim 1, wherein the first filler particles have a form of an ellipse or a sphere.

14. A semiconductor package comprising:
a substrate;
one or more external connection terminals bonded to a first surface of the substrate;
at least one semiconductor device on the substrate;
a mold layer on a second surface of the substrate and at least a surface of the at least one semiconductor device;
at least two internal connection members between the at least one semiconductor device and the substrate, and configured to connect the at least one semiconductor device and the substrate; and
an underfill layer between the at least one semiconductor device and the substrate, and configured to fill spaces between the at least two internal connection members,
wherein the underfill layer comprises a first resin layer and first filler particles dispersed in the first resin layer,
wherein at least one of the first filler particles comprises a first core portion and a first coating layer surrounding the first core portion,
wherein the first core portion comprises at least one of graphene, carbon nanotube, diamond, or graphite,
wherein the first coating layer has a structure of a single layer or a structure of multiple layers,
wherein the first coating layer comprises at least one of silica, alumina, magnesium oxide, or boron nitride, and
wherein at least one of the first filler particles has a form of an ellipse or a sphere.

15. The semiconductor package of claim 14, wherein the underfill layer further comprises second filler particles in the first resin layer,
wherein at least one of the second filler particles has a structure of a single layer or a structure of multiple layers, and
wherein the second filler particles comprise at least one of silica, alumina, magnesium oxide, or boron nitride.

16. The semiconductor package of claim 14, wherein the mold layer comprises a second resin layer and second filler particles in the second resin layer,
wherein each of the second filler particles comprises a second core portion and a second coating layer surrounding at least a portion of the second core portion,
wherein the second core portion comprises at least one of graphene, carbon nanotube, diamond, or graphite,
wherein the second coating layer has a structure of a single layer or a structure of multiple layers, and
wherein the second coating layer comprises at least one of silica, alumina, magnesium oxide, or boron nitride.

17. The semiconductor package of claim 14, wherein the first filler particles have a diameter of about 0.1 μm to about 100 μm.

18. A semiconductor package comprising:
a substrate;
a semiconductor device on the substrate;
an adhesive layer between the semiconductor device and the substrate; and
a mold layer on a first surface of the semiconductor device and a surface of the substrate,
wherein the adhesive layer comprises a first resin layer and first filler particles in the first resin layer,
wherein at least one of the first filler particles comprises a first core portion and a first coating layer surrounding at least a portion of the first core portion,
wherein the first core portion comprises a carbon material, and
wherein the first coating layer comprises a carbon-excluded inorganic material.

19. The semiconductor package of claim 18, wherein the mold layer comprises a second resin layer and second filler particles in the second resin layer,
wherein at least one of the second filler particles comprises a second core portion and a second coating layer surrounding at least a portion of the second core portion,
wherein the second core portion comprises at least one of graphene, carbon nanotube, diamond, or graphite,
wherein the second coating layer has a structure of a single layer or a structure of multiple layers, and
wherein the second coating layer comprises at least one of silica, alumina, magnesium oxide, or boron nitride.

20. The semiconductor package of claim 19, wherein the mold layer extends to be on a second surface of the semiconductor device,
wherein the mold layer comprises a first mold part on the second surface of the semiconductor device and a second mold part on the first surface of the semiconductor device, and
wherein a number of the second filler particles per unit area in the first mold part is greater than a number of the second filler particles per unit area in the second mold part.
